(19) United States
(12) Patent Application Publication
(10) Pub. No.: US 2023/0093818 A1
(43) Pub. Date: Mar. 30, 2023

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takeshi MURASAKI, Yokohama Kanagawa (JP); Tadashi ARAI, Yokohama Kanagawa (JP); Makoto ARAI, Tachikawa Tokyo (JP); Shoji OOTAKA, Yokohama Kanagawa (JP); Yusuke IMAIZUMI, Kawasaki Kanagawa (JP)

(21) Appl. No.: 17/684,125

(22) Filed: Mar. 1, 2022

(30) Foreign Application Priority Data
Sep. 24, 2021 (JP) 2021-155719

(51) Int. Cl. H02J 50/10; H01L 23/66; H05K 1/16

(52) U.S. Cl. CPC H02J 50/10; H01L 23/66; H05K 1/165; H01L 2223/6605

(57) ABSTRACT

A semiconductor device includes: a first semiconductor chip including a first coil that generates a magnetic field signal; a wiring board including a second coil, a third coil, and a twisted pair wiring, the second coil being disposed to face the first coil and receiving the magnetic field signal generated by the first coil, the twisted pair wiring connecting the second coil with the third coil; and a second semiconductor chip including a fourth coil disposed to face the third coil and receiving a magnetic field signal generated by the third coil.

### CROSS-REFERENCE TO RELATED APPLICATIONS

This application is based upon and claims the benefit of priority from the prior Japanese Patent Application No. 2021-155719 filed on Sep. 24, 2021; the entire contents of which are incorporated herein by reference.

### FIELD

Embodiments described herein relate generally to a semiconductor device including two semiconductor chips that can achieve both electrical insulation and signal transmission.

### BACKGROUND

For example, to transmit a signal in a state where a first semiconductor chip and a second semiconductor chip are electrically insulated from each other, a wiring board is used that is inductively coupled via a second coil disposed to face a first coil of the first semiconductor chip. The wiring board includes a third coil and two wirings, the third coil being inductively coupled to a fourth coil of the second semiconductor chip, the two wirings connecting the second coil with the third coil.

When an external magnetic field is applied to the wirings of the wiring board, an electric current flows through the coils, thus inducing a differential current due to a magnetic field which causes a disturbance. Such an external magnetic field may be blocked by shielding, for example.

### BRIEF DESCRIPTION OF THE DRAWINGS

FIG. 1 is a top plan view of a semiconductor device of a first embodiment;

FIG. 2 is a configuration diagram of the semiconductor device of the first embodiment;

FIG. 3 is an exploded perspective view of the semiconductor device of the first embodiment;

FIG. 4 is a perspective view of a wiring board of the first embodiment;

FIG. 5 is a configuration diagram of a semiconductor device of a modification of the first embodiment:

FIG. 6 is a transparent perspective view of the semiconductor device of the modification of the first embodiment;

FIG. 7 is a configuration diagram of a semiconductor device of a second embodiment;

FIG. 8 is a transparent perspective view of the semiconductor device of the second embodiment;

FIG. 9 is an exploded perspective view of a wiring board of the semiconductor device of the second embodiment;

FIG. 10 is an exploded perspective view of a wiring board of a semiconductor device of modification 1 of the second embodiment;

FIG. 11 is a configuration diagram of a semiconductor device of modification 2 of the second embodiment; and

FIG. 12 is a schematic view of a configuration of the semiconductor device of the modification 2 of the second embodiment.

### DETAILED DESCRIPTION

A semiconductor device includes: a first semiconductor chip including a first coil that generates a magnetic field signal; a wiring board including a second coil, a third coil, and a twisted pair wiring, the second coil being disposed to face the first coil and receiving the magnetic field signal generated by the first coil, the twisted pair wiring connecting the second coil with the third coil; and a second semiconductor chip including a fourth coil disposed to face the third coil and receiving a magnetic field signal generated by the third coil.

### First Embodiment

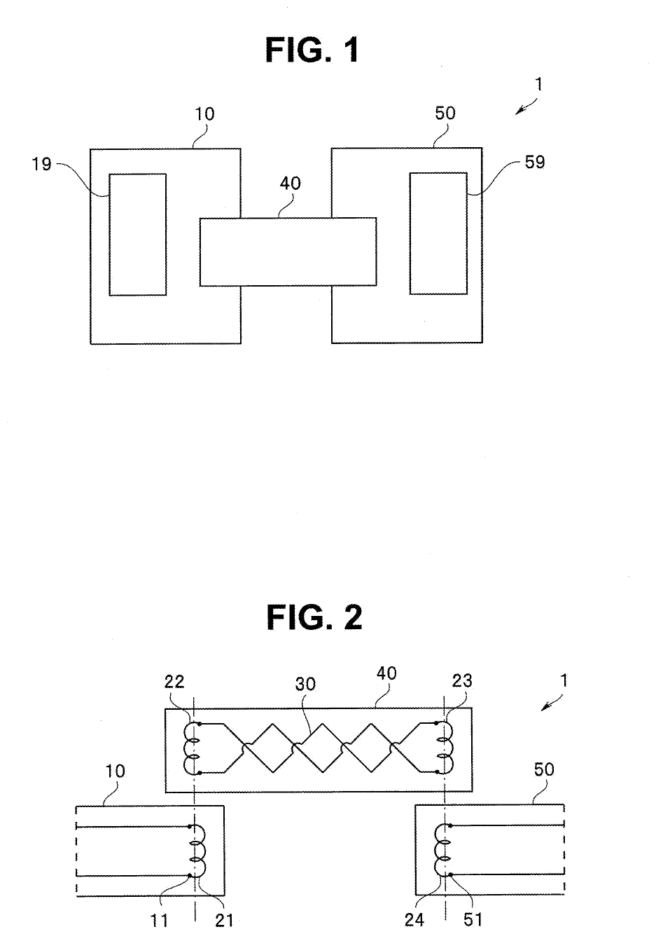

As shown in FIG. 1, a semiconductor device 1 of the present embodiment includes a first semiconductor chip 10, a wiring board 40, and a second semiconductor chip 50. The semiconductor device 1 is a semiconductor package where the wiring board 40 and the like are sealed by sealing resin not shown in the drawing.

The first semiconductor chip 10 includes a primary circuit 19. The second semiconductor chip 50 includes a secondary circuit 59. Each of the primary circuit 19 and the secondary circuit 59 includes a signal demodulation circuit and a signal transmission/reception circuit, for example.

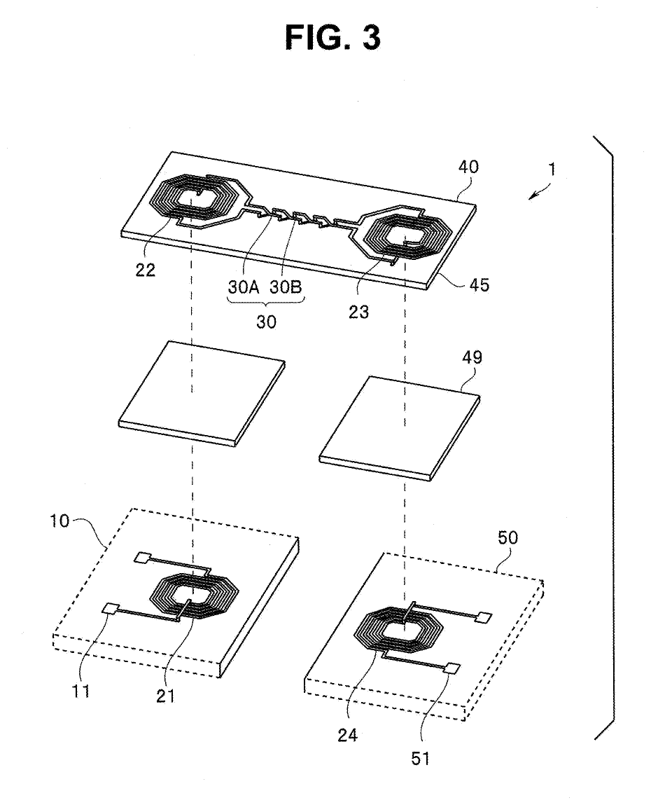

As shown in FIG. 2 to FIG. 4, the wiring board 40 is fixed to the first semiconductor chip 10 and the second semiconductor chip 50 by using a non-conductive adhesive agent 49. The first semiconductor chip 10 includes a first coil 21. Although not shown in the drawing, terminals 11 of the first coil 21 are connected with the primary circuit 19 of the first semiconductor chip 10. The first coil 21 converts an electric signal outputted from the primary circuit 19 to a magnetic field signal.

The second semiconductor chip 50 includes a fourth coil 24. Although not shown in the drawing, terminals 51 of the fourth coil 24 are connected with the secondary circuit 59 of the second semiconductor chip 50. The fourth coil 24 is disposed to face a third coil 23, receives a magnetic field signal generated by the third coil 23, and converts the magnetic field signal to an electric signal.

The wiring board 40 includes a second coil 22, the third coil 23, and a wiring 30, the second coil 22 being disposed to face the first coil 21, the wiring 30 connecting the second coil 22 with the third coil 23. The second coil 22 receives a magnetic field signal generated by the first coil 21, converts the magnetic field signal to an electric signal, and transmits the electric signal to the third coil 23 via the wiring 30. The third coil 23 converts the electric signal to a magnetic field signal. To reduce the influence of a disturbance, it is preferable to set a length L of the wiring 30 to 10 mm or less. For example, the length L of the wiring 30 may be 3 mm.

Hereinafter, each of the first coil 21, the second coil 22, the third coil 23, and the fourth coil 24 is referred to as a “coil 20”.

The wiring 30 is a twisted pair wiring where two wirings 30A, 30B intersect with each other four times. In the twisted pair wiring, an equivalent electric current flows through the two wirings in opposite directions and hence, the twisted pair wiring has the advantageous effect of canceling the influence of noise entering from the surrounding.

It is sufficient that the two wirings 30A, 30B of the wiring 30 intersect with each other at least one time. To cancel the influence of a disturbance which is locally applied, it is preferable that the two wirings 30A, 30B intersect with each other two or more times. An example of the upper limit for the number of intersections is two times/mm, wherein the increase in resistance falls within an allowable range. For example, the upper limit for the number of intersections of the wiring 30 with the length L of 5 mm is ten times.

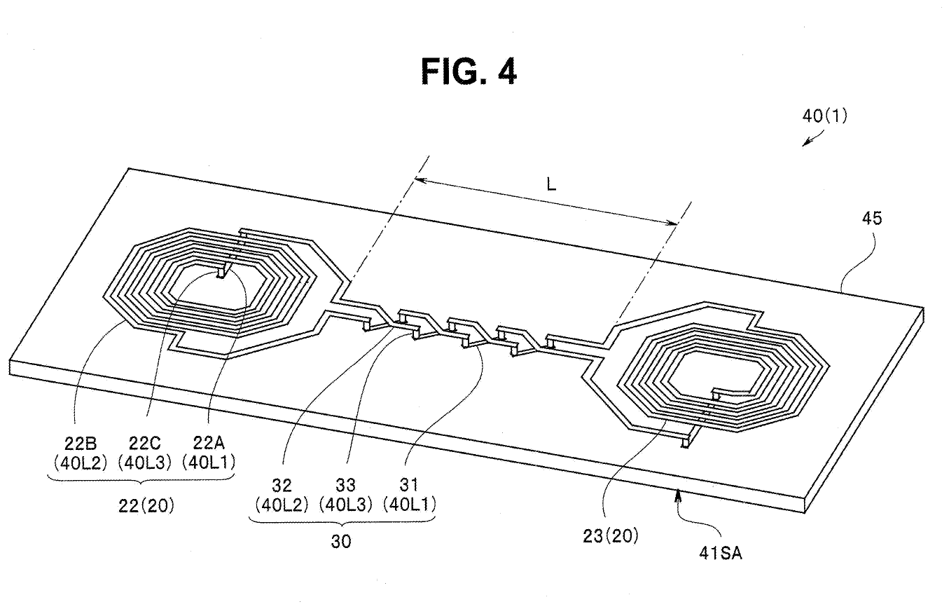

As shown in FIG. 4, each of the coil 20 and the wiring 30 is formed from a plurality of conductor patterns. For example, the wiring 30 is formed of a plurality of first wiring patterns 31, a plurality of second wiring patterns 32, a plurality of connection wiring patterns 33, and an insulation layer (not shown in the drawing).

The wiring 30 includes the plurality of first wiring patterns 31, the plurality of second wiring patterns 32, and the plurality of connection wiring patterns 33. For example, a first wiring layer 40L1 including the plurality of first wiring patterns 31 is formed on a non-conductive substrate 45. The insulation layer (not shown in the drawing) that covers the first wiring layer 40L1 has through holes for connecting the first wiring patterns 31 with the second wiring patterns 32, and a connection wiring layer 40L3, which is a third wiring layer including the connection wiring patterns 33, is formed in the through holes. In the case where unevenness is formed on the surface of the insulation layer, which covers the first wiring layer 40L1, a flattening process is performed. A second wiring layer 40L2 including the plurality of second wiring patterns 32 is formed on the insulation layer. That is, the connection wiring layer 40L3 including the plurality of connection wiring patterns 33 is formed between the first wiring layer 40L1 and the second wiring layer 40L2.

In the same manner as the wiring 30, for example, in the second coil 22, the first wiring layer 40L1 includes a first coil pattern 22A and the second wiring layer 40L2 includes a second coil pattern 22B. The connection wiring layer 40L3 includes coil connection wiring patterns 22C that connect the first coil pattern 22A with the second coil pattern 22B. The first coil pattern 22A is formed of a leader wiring and the second coil pattern 22B is formed of a spiral coil. A configuration may be adopted where the first coil pattern 22A is formed of a spiral coil and the second coil pattern 22B is formed of a leader wiring.

The second coil 22, the third coil 23, and the wiring 30 are formed simultaneously. For example, when a so-called additive method is adopted, each of the first wiring layer 40L1, the connection wiring layer 40L3, and the second wiring layer 40L2 is formed in such a manner that a base conductive layer film is formed on the principal surface of the substrate 45, a pattern is formed by photolithography, and an electroplating film is formed. The insulation layer is formed by using photosensitive resin, such as polyimide. Glass epoxy resin, polyimide resin, silicon, or the like is used for forming the substrate 45.

When the subtractive method is adopted, each of the first wiring layer 40L1, the connection wiring layer 40L3, and the second wiring layer 40L2 is formed in such a manner that a conductive film is formed on the entire substrate 45 and, thereafter, a pattern is formed by photolithography and etching is performed. A configuration may be adopted where the first wiring layer 40L1 is formed by the subtractive method and the connection wiring layer 40L3 and the second wiring layer 40L2 are formed by the additive method. In the case where the connection wiring layer 40L3 and the second wiring layer 40L2 are formed by the additive method, the connection wiring layer 40L3 and the second wiring layer 40L2 may be simultaneously formed as an integral body by performing a plating step one time.

In forming the wiring 30, a configuration may be adopted where the first wiring layer 40L1 is formed on the first principal surface of the substrate 45, the second wiring layer 40L2 is formed on the second principal surface, which is disposed on a side opposite to the first principal surface, and the connection wiring layer 40L3 is formed of a plurality of through wirings. That is, the substrate 45 may be used as the insulation layer.

When the substrate 45 of the wiring board 40 is used as the insulation layer formed between the first wiring layer 40L1 and the second wiring layer 40L2, a semiconductor device can be easily manufactured.

Each of the second coil 22 and the third coil 23 is formed of a spiral coil pattern and a leader wiring pattern. However, the coil 20 may have a spiral coil pattern of two or more layers.

Each of the first coil 21 and the fourth coil 24 has a configuration substantially equal to the configuration of the second coil 22. Each of the first coil 21 and the fourth coil 24 is formed by the additive method having high compatibility with a silicon semiconductor process.

The coil 20 described as an example is a 4.5 turn coil. However, the number of turns may be suitably set. The four coils 20 may differ from each other in the number of turns.

In the semiconductor device 1, the wiring that connects the second coil 22 with the third coil 23 is a twisted pair wiring. Therefore, the semiconductor device 1 is not easily affected by a disturbance and does not require shielding, thus having high transmission efficiency.

Further, the wiring 30 is a so-called thin film wiring that includes the first wiring layer 40L1, the second wiring layer 40L2, and the connection wiring layer 40L3 formed between the first wiring layer 40L1 and the second wiring layer 40L2, the first wiring layer 40L1 including the plurality of first wiring patterns 31, the second wiring layer 40L2 including the plurality of second wiring patterns 32, the connection wiring layer 40L3 including the plurality of connection wiring patterns 33 each of which connects each of the plurality of first wiring patterns 31 with each of the plurality of second wiring patterns 32. Therefore, although the length L of the wiring 30 is short, the wiring 30 can be easily manufactured.

Simultaneously with the formation of the wiring 30, being a thin film wiring, the second coil 22 and the third coil 23 are formed in the same step.

### Modification of First Embodiment

A semiconductor device 1A of a modification of the first embodiment is similar to the semiconductor device 1 and hence, constitutional elements having the same function are given the same reference symbols, and the description of such constitutional elements will be omitted.

The semiconductor device 1 has a double insulation structure where the first semiconductor chip 10 and the second semiconductor chip 50 are insulated from each other at two portions, that is, between the first coil 21 and the second coil 22 and between the third coil 23 and the fourth coil 24. In contrast, in the semiconductor device 1A, the first semiconductor chip 10 and a second semiconductor chip 50B are insulated from each other only between the first coil 21 and the second coil 22.

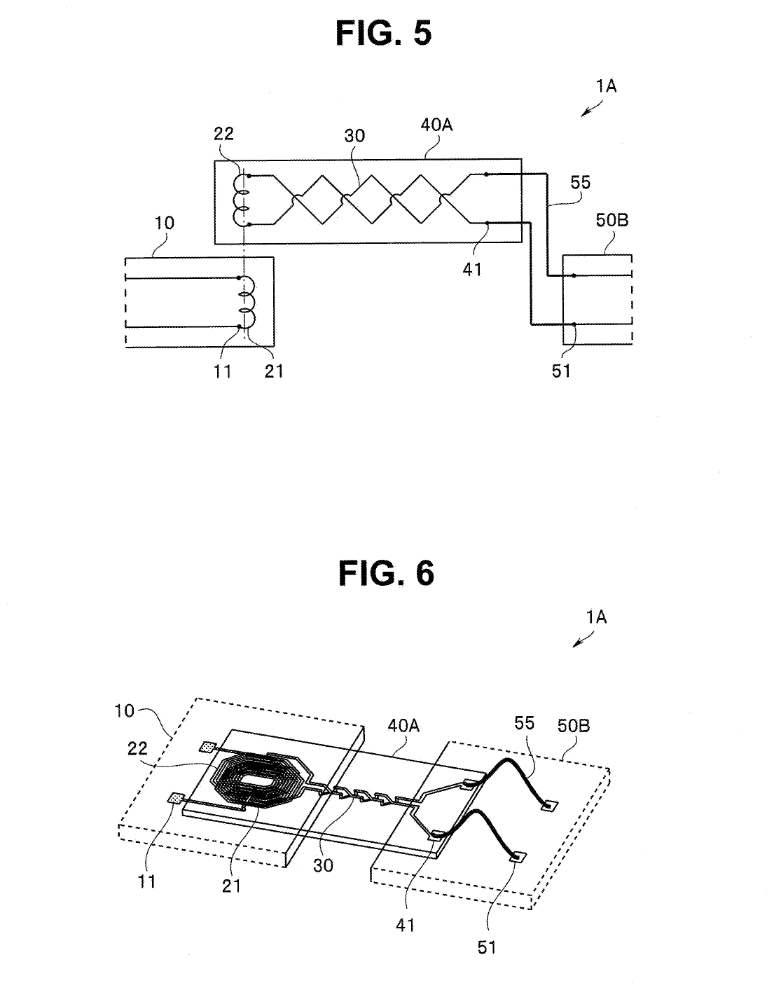

As shown in FIG. 5 and FIG. 6, in the semiconductor device 1A, a wiring board 40A includes no third coil. The second semiconductor chip 50B includes no fourth coil. The second coil 22 of the wiring board 40A includes terminals 41.

Terminals 51 of the second semiconductor chip 50B are connected with the terminals 41 of the wiring board 40A via bonding wires 55. For wire bonding, it is preferable that a gold layer be formed on the uppermost layer of each of the terminals 41, 51. The terminals 41 may be bonded to the terminals 51 by soldering.

In the semiconductor device 1A, although the second semiconductor chip 50B includes no coil, the first semiconductor chip 10 can be connected with the second semiconductor chip 50B in an insulated state. In the semiconductor device 1, an electric signal outputted from the first semiconductor chip 10 is differentiated two times, and is then transmitted to the second semiconductor chip 50. In contrast, in the semiconductor device 1A, an electric signal outputted from the first semiconductor chip 10 is differentiated one time, and is then transmitted to the second semiconductor chip 50B. Therefore, in the semiconductor device 1A, signal processing can be more easily performed by the second semiconductor chip SOB compared with the semiconductor device 1.

### Second Embodiment

A semiconductor device 1B of a second embodiment is similar to the semiconductor device 1 and hence, constitutional elements having the same function are given the same reference symbols, and the description of such constitutional elements will be omitted.

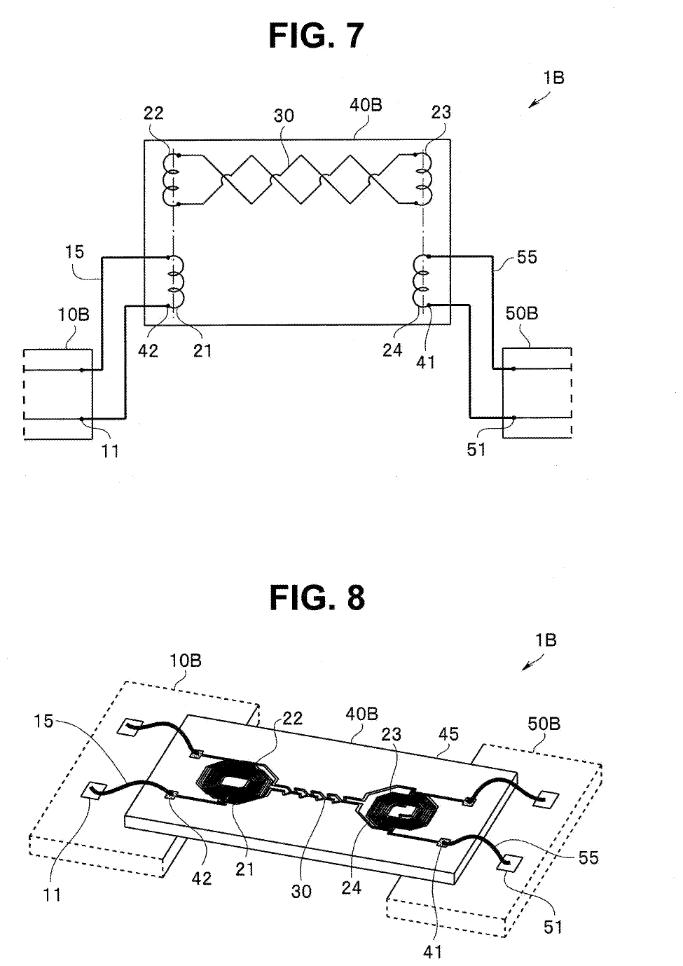

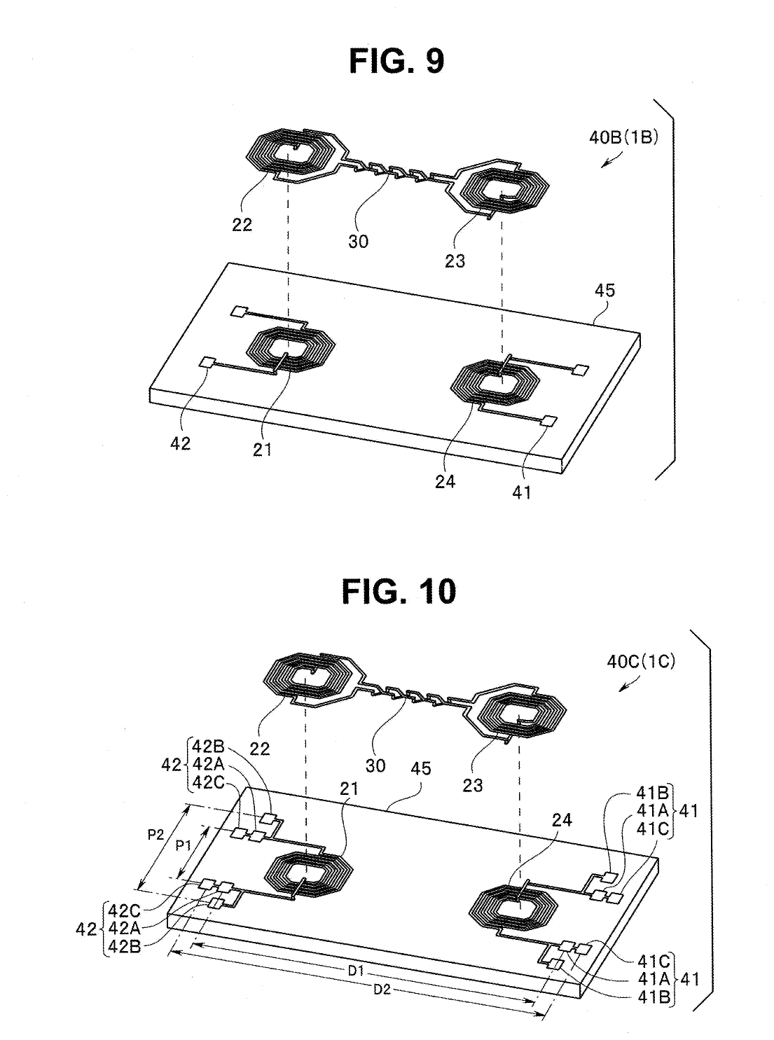

As shown in FIG. 7 to FIG. 9, in the semiconductor device 1B, neither a first semiconductor chip 10B nor the second semiconductor chip 50B includes a coil for connecting the first semiconductor chip 10B or the second semiconductor chip 50B with a wiring board 40B. The wiring board 40B includes the first coil 21, the second coil 22, the third coil 23, and the fourth coil.

Terminals 42 of the first coil 21 are connected with the terminals of the first semiconductor chip 10B. The terminals 41 of the fourth coil are connected with the terminals of the second semiconductor chip SOB.

For example, the first coil 21 and the fourth coil 24 are formed on the substrate 45 and, thereafter, via an intermediate insulation layer (not shown in the drawing) made of polyimide or the like, the second coil 22, the third coil 23, and the wiring 30 are formed, the wiring 30 connecting the second coil 22 with the third coil 23.

The wiring board 40B may be formed in such a manner that the first coil 21 and the fourth coil 24 are formed on the substrate 45, and an insulating substrate, on which the second coil 22, the wiring 30, and the third coil 23 are formed and which is made of polyimide or the like, is stuck to the substrate 45. Alternatively, the wiring board 40B may be formed in such a manner that the first coil 21 and the fourth coil 24 are formed on the first principal surface of the substrate 45, and the wiring 30 and the third coil 23 are formed on the second principal surface disposed on a side opposite to the first principal surface.

In the semiconductor device 1B, it is not necessary to form a coil on either the first semiconductor chip 10B or the second semiconductor chip 50B. In other words, in the semiconductor device 1B, the first semiconductor chip 10B and the second semiconductor chip 50B, neither of which includes a coil, can be connected with each other in an insulated state.

### Modification of Second Embodiment

Each of semiconductor devices 1C, 1D of modifications of the second embodiment is similar to the semiconductor device 1B and hence, constitutional elements having the same function are given the same reference symbols, and the description of such constitutional elements will be omitted.

### Modification 1 of Second Embodiment

As shown in FIG. 10, a wiring board 40C of a semiconductor device 1C of the present modification includes not only first terminals 41A, 42A but also second terminals 41B, 41C, 42B, 42C. The first terminals 41A, 42A are bonded to the terminals 11, 51 of the first semiconductor chip 10 by using solders 15A, 55A. The second terminals 41B, 41C, 42B, 42C are connected with the first coil 21 without being bonded to the first semiconductor chip 10B.

For example, a separation P2 between a set of second terminals 42B differs from a separation P1 between a set of first terminals 42A. A separation D2 between the second terminal 42C and the second terminal 41C differs from a separation D1 between the first terminal 42A and the first terminal 41A.

The terminals 42B, 42C, 41B, 41C are used for bonding the wiring board 40C to a semiconductor chip having terminals with a separation larger than the separation P or the separation D between the terminals of the first semiconductor chip 10. That is, by forming a plurality of sets of terminals on the wiring board in advance, the wiring board can be bonded to a semiconductor chip having a different separation between terminals, for example.

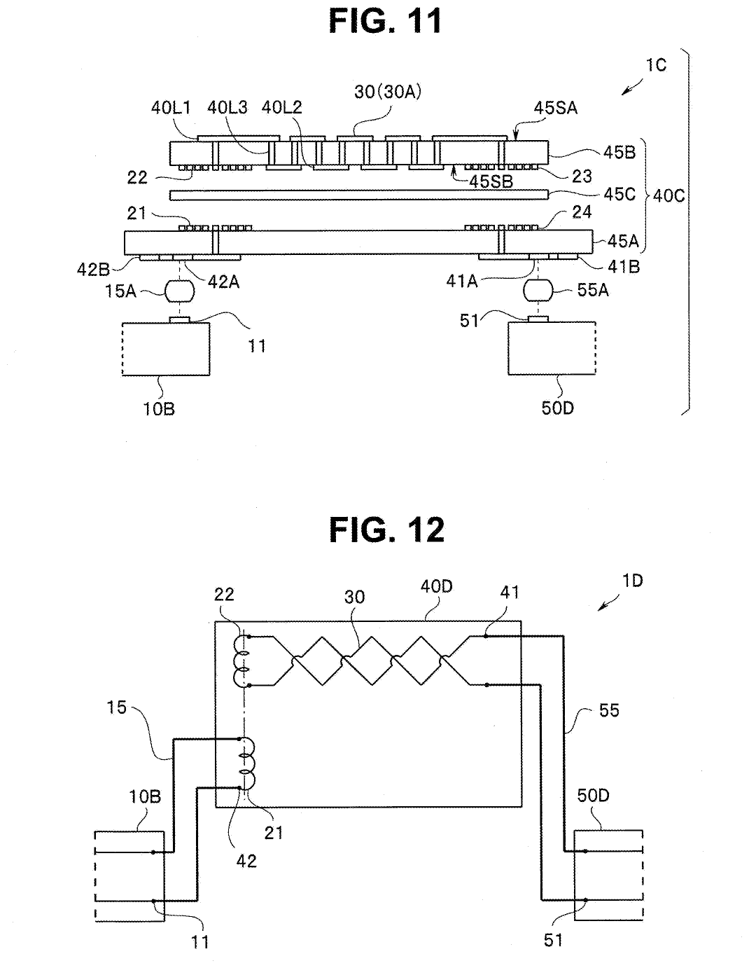

As shown in FIG. 11, in the wiring board 40C, a first substrate 45A and a second substrate 45B are caused to adhere to each other with an intermediate insulation layer 45C. For example, the first substrate 45A is made of glass epoxy resin, and the second substrate 45B is made of polyimide. FIG. 11 is a view for describing the configuration of the semiconductor device 1C, but is not a cross-sectional view.

The first coil 21 and the fourth coil 24 are formed on the first substrate 45A. The second coil 22, the wiring 30 (30A, 30B), and the third coil 23 are formed on the second substrate 45B.

For example, the first wiring layer 40L1 is formed on a first principal surface 45SA of the second substrate 45B, the second wiring layer 40L2 is formed on a second principal surface 45SB of the second substrate 45B on a side opposite to the first principal surface 45SA, and the connection wiring layer 40L3 is formed of a plurality of through wirings formed in the second substrate 45B.

### Modification 2 of Second Embodiment

The semiconductor device 1C has the double insulation structure where the first semiconductor chip 10B and the second semiconductor chip 50B are insulated from each other at two portions, that is, between the first coil 21 and the second coil 22 and between the third coil 23 and the fourth coil 24. In contrast, in a semiconductor device 1D, the first semiconductor chip 10B and a second semiconductor chip 50D are insulated from each other only between the first coil 21 and the second coil 22.

As shown in FIG. 12, in the semiconductor device 1D, a wiring board 40D includes neither the third coil nor the fourth coil. The terminals 51 of the second semiconductor chip 50D are bonded to the terminals 41 of the wiring board 40D by using solders. The terminals 51 and the terminals 41 may be wire-bonded to each other.

The wiring board 40D does not require a flattening process for an interlayer insulation layer, thus being easily formed compared with the wiring board 40C. Therefore, the semiconductor device 1D can be manufactured more easily at a low cost compared with the semiconductor device 1C.

The semiconductor device 1D has advantageous effects substantially equal to the advantageous effects obtained by the semiconductor devices 1A, 1B, 1C.

The first semiconductor chip 10 may be connected with each of a plurality of semiconductor chips via any one of the wiring boards 40, 40A to 40D.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first semiconductor chip including a first coil that generates a magnetic field signal;
a wiring board including a second coil, a third coil, and a twisted pair wiring, the second coil being disposed to face the first coil and receiving the magnetic field signal generated by the first coil, the twisted pair wiring connecting the second coil with the third coil; and
a second semiconductor chip including a fourth coil disposed to face the third coil and receiving a magnetic field signal generated by the third coil.

2. The semiconductor device according to claim 1, wherein
the twisted pair wiring includes
a first wiring layer including a plurality of first wiring patterns,
a second wiring layer including a plurality of second wiring patterns, and
a connection wiring layer formed between the first wiring layer and the second wiring layer, the connection wiring layer including a plurality of connection wiring patterns each of which connects each of the plurality of first wiring patterns with each of the plurality of second wiring patterns.

3. The semiconductor device according to claim 2, wherein in the second coil,
the first wiring layer includes a first coil pattern,
the second wiring layer includes a second coil pattern, and
the connection wiring layer includes a coil connection wiring pattern that connects the first coil pattern with the second coil pattern.

4. The semiconductor device according to claim 2, wherein the second wiring layer and the connection wiring layer form an integral wiring layer.

5. The semiconductor device according to claim 2, wherein the first wiring layer is formed on a first principal surface of a substrate,
the second wiring layer is formed on a second principal surface of the substrate on a side opposite to the first principal surface, and
the connection wiring layer is formed of a plurality of through wirings formed in the substrate.

6. A semiconductor device comprising:
a first semiconductor chip including a first coil that generates a magnetic field signal;
a wiring board including a second coil and a twisted pair wiring, the second coil being disposed to face the first coil and receiving the magnetic field signal generated by the first coil, the twisted pair wiring being connected with the second coil; and
a second semiconductor chip connected with the twisted pair wiring.

7. The semiconductor device according to claim 6, wherein the twisted pair wiring includes
a first wiring layer including a plurality of first wiring patterns,
a second wiring layer including a plurality of second wiring patterns, and
a connection wiring layer formed between the first wiring layer and the second wiring layer, the connection wiring layer including a plurality of connection wiring patterns each of which connects each of the plurality of first wiring patterns with each of the plurality of second wiring patterns.

8. The semiconductor device according to claim 7, wherein in the second coil,
the first wiring layer includes a first coil pattern,
the second wiring layer includes a second coil pattern, and
the connection wiring layer includes a coil connection wiring pattern that connects the first coil pattern with the second coil pattern.

9. The semiconductor device according to claim 7, wherein the second wiring layer and the connection wiring layer form an integral wiring layer.

10. The semiconductor device according to claim 7, wherein the first wiring layer is formed on a first principal surface of a substrate,
the second wiring layer is formed on a second principal surface of the substrate on a side opposite to the first principal surface, and
the connection wiring layer is formed of a plurality of through wirings formed in the substrate.

11. A semiconductor device comprising:
a first semiconductor chip;
a wiring board including a first coil, a second coil, a third coil, a twisted pair wiring, and a fourth coil, the first coil being connected with the first semiconductor chip, the second coil being disposed to face the first coil and receiving a magnetic field signal generated by the first coil, the twisted pair wiring connecting the second coil with the third coil, the fourth coil receiving a magnetic field signal generated by the third coil; and
a second semiconductor chip connected with the fourth coil.

12. The semiconductor device according to claim 11, wherein the wiring board includes a second terminal disposed at a position different from a position of a first terminal bonded to the first semiconductor chip by soldering, the second terminal being connected with the first coil without being bonded to the first semiconductor chip by soldering.

13. The semiconductor device according to claim 11, wherein the twisted pair wiring includes
a first wiring layer including a plurality of first wiring patterns,
a second wiring layer including a plurality of second wiring patterns, and
a connection wiring layer formed between the first wiring layer and the second wiring layer, the connection wiring layer including a plurality of connection wiring patterns each of which connects each of the plurality of first wiring patterns with each of the plurality of second wiring patterns.

14. The semiconductor device according to claim 13, wherein in the second coil,
the first wiring layer includes a first coil pattern,
the second wiring layer includes a second coil pattern, and
the connection wiring layer includes a coil connection wiring pattern that connects the first coil pattern with the second coil pattern.

15. The semiconductor device according to claim 13, wherein the second wiring layer and the connection wiring layer form an integral wiring layer.

16. The semiconductor device according to claim 13, wherein the first wiring layer is formed on a first principal surface of a substrate,
the second wiring layer is formed on a second principal surface of the substrate on a side opposite to the first principal surface, and
the connection wiring layer is formed of a plurality of through wirings formed in the substrate.

17. A semiconductor device comprising:
a first semiconductor chip;
a wiring board including a first coil, a second coil, and a twisted pair wiring, the first coil being connected with the first semiconductor chip, the second coil being disposed to face the first coil and receiving a magnetic field signal generated by the first coil, the twisted pair wiring being connected with the second coil; and
a second semiconductor chip connected with the twisted pair wiring.

18. The semiconductor device according to claim 17, wherein the wiring board includes a second terminal disposed at a position different from a position of a first terminal bonded to the first semiconductor chip by soldering, the second terminal being connected with the first coil without being bonded to the first semiconductor chip by soldering.

19. The semiconductor device according to claim 17, wherein the twisted pair wiring includes
a first wiring layer including a plurality of first wiring patterns,
a second wiring layer including a plurality of second wiring patterns, and
a connection wiring layer formed between the first wiring layer and the second wiring layer, the connection wiring layer including a plurality of connection wiring patterns each of which connects each of the plurality of first wiring patterns with each of the plurality of second wiring patterns.

20. The semiconductor device according to claim 19, wherein in the second coil,
the first wiring layer includes a first coil pattern,
the second wiring layer includes a second coil pattern, and
the connection wiring layer includes a coil connection wiring pattern that connects the first coil pattern with the second coil pattern.

21. The semiconductor device according to claim 19, wherein the second wiring layer and the connection wiring layer form an integral wiring layer.

22. The semiconductor device according to claim 19, wherein the first wiring layer is formed on a first principal surface of a substrate,
the second wiring layer is formed on a second principal surface of the substrate on a side opposite to the first principal surface, and
the connection wiring layer is formed of a plurality of through wirings formed in the substrate.
